(19) United States
(12) Patent Application Publication
(10) Pub. No.: US 2017/0169929 A1
(43) Pub. Date: Jun. 15, 2017

(54) INDUCTIVE COMPONENT FOR USE IN AN INTEGRATED CIRCUIT, A TRANSFORMER AND AN INDUCTOR FORMED AS PART OF AN INTEGRATED CIRCUIT

(71) Applicant: ANALOG DEVICES GLOBAL, Hamilton (BM)

(72) Inventor: Jan Kubik, Raheen (IE)

(21) Appl. No.: 14/967,059

(22) Filed: Dec. 11, 2015

(51) Int. Cl. H01F 27/28; H01F 41/04; H01F 27/24

(52) U.S. Cl. CPC H01F 27/2804; H01F 27/24; H01F 41/041; H01F 2027/2809

(57) ABSTRACT

Inductive components, such as transformers, can be improved by the inclusion of a magnetic core. However, the benefit of having a core is lost if the core enters magnetic saturation. One way to avoid saturation is to provide a bigger core, but this is costly in the context of integrated electronic circuits. The inventor realized that the magnetic flux density varies with position in a magnetic core within certain integrated circuits, causing parts of the magnetic core to saturate earlier than other parts. This reduces the ultimate performance of the magnetic core. This disclosure provides structures that delay the onset of early saturation, which can, for example, enable a transformer to handle more power.

### TECHNICAL FIELD

The present disclosure relates to an improved inductor or improved transformer fabricated using microelectronic techniques, and to integrated circuits including such an inductive component.

### DESCRIPTION OF THE RELATED ART

It is known that magnetic components, such as inductors and transformers have many uses. For example inductors may be used in the fabrication of filters and resonant circuits, or may be used in switched mode power converters to boost or reduce an input voltage for generation of a different output voltage. Transformers may be used in the transfer of power or signals from one circuit to another while providing high levels of galvanic isolation.

Inductors and transformers can be fabricated within an integrated circuit environment. For example it is known that spaced apart conductors generally forming a spiral or an approximation of a spiral can be formed on or within a semiconductor substrate to form a coil as part of an inductor or a transformer. Such spaced apart spiral inductors can be placed side by side or in a stacked configuration.

It is also possible to form ferromagnetic core around a “coil” within an integrated circuit. However such an arrangement exhibits non-linearities in its behavior. It would be beneficial to provide an improved component within an integrated circuit.

### SUMMARY

The methods and devices of the described technology each have several aspects, no single one of which is solely responsible for its desirable attributes.

Inductive components, such as transformers, can be improved by the inclusion of a magnetic core. However, the benefit of having a core can be lost if the core enters magnetic saturation. One way to avoid saturation is to provide a bigger core, but this is costly in the context of integrated electronic circuits. The inventor realized that the magnetic flux density varies with position in a magnetic core within certain integrated circuits, causing parts of the magnetic core to saturate earlier than other parts. This reduces the ultimate performance of the magnetic core. This disclosure provides structures that delay the onset of early saturation, which can, for example, enable a transformer to handle more power.

According to a first aspect of the present disclosure there is provided an inductive component for use in an integrated circuit, comprising: at least one conductor arranged in a spiral path to form a first coil; a first layer of magnetic material arranged on or adjacent at least a portion of a first side of the conductor to form at least one magnetic core; and a compensation structure for compensating for core saturation non-uniformity.

It is thus possible to provide a magnetic component on or as part of an integrated circuit where the magnetic core saturates more uniformly. This in turn can give rise to greater linearity and improved power transfer within an operating region where substantially none of the core has reached magnetic saturation. This can be achieved without incurring an increased footprint for the magnetic component on a substrate, such as a semiconductor, on which the magnetic component is carried.

The compensation structure may comprise varying a parameter of the first coil. The parameter may be a turns density of the first coil, which may be achieved by varying a pitch of the conductors as they traverse from one side of the coil to the other; a spacing between the conductors; or a width of the conductors. Two or more of parameters may be varied in combination. Where the inductive component comprises a plurality of coils, for example because it is a transformer, then parameters of the second coil may also be varied as described above.

Advantageously, in an embodiment of this disclosure, a conductor width of the conductors forming the first coil increases with increasing distance from an edge of the spiral path, and preferably from both edges of the spiral path. This arrangement has the advantage of reducing the effective turns density of the coil around sections of the magnetic core which are located away from the edges of the spiral, while at the same time avoiding unnecessary increase in the resistance of the coil.

Advantageously the inductive component is formed on a substrate that carries other integrated circuit components. The substrate may be a semiconductor substrate, the most common example of which is silicon. However, other substrates may be used and may be chosen for operation at relatively high frequencies. Such a substrate may include glass, or other semiconductors such as germanium.

According to a second aspect of the present disclosure a method of forming a inductive component comprising depositing a first layer of magnetic material on a substrate; forming an insulator above the first layer of magnetic material; forming at least one conductor arranged in a spiral path to form a first coil above the insulator; forming an insulating layer above the at least one conductor; forming a second layer of magnetic material above the insulating layer, so as to form a magnetic core with said first layer of magnetic material; where the first coil is arranged to form a compensation structure for compensating for core saturation non-uniformity.

### BRIEF DESCRIPTION OF THE DRAWINGS

Embodiments of this disclosure will now be described, by way of non-limiting example only, with reference to the accompanying drawings, in which:

FIG. 1 is a schematic plan view of a transformer formed within an integrated circuit;

FIG. 2 is a schematic cross section through the transformer of FIG. 1;

FIG. 3 is a perspective view of a transformer formed within an integrated circuit;

FIG. 4 is a cross section through the transformer of FIG. 3;

FIG. 5 is a circuit diagram showing a circuit for measuring flux density as a function of coil current;

FIG. 6 shows a graph of flux density versus coil current for a typical transformer on an integrated circuit;

FIG. 7 is a graph of flux density versus coil current having straight line approximations to the response of the coil added thereto for the purposes of explaining the advantages of the present disclosure;

FIG. 8 is a graph representing turns density as a function of position along a coil axis for a coil surrounding a rectangular magnetic core;

FIG. 9 is a schematic view of an inductor or transformer in accordance with the present disclosure;

FIG. 10 is a schematic cross section through a device in accordance with an embodiment of this disclosure;

FIG. 11 is a schematic cross section through a transformer in accordance with an embodiment of this disclosure;

FIG. 12 is a schematic plan view of a transformer in accordance with an embodiment of this disclosure;

FIG. 13 is a schematic plan view of a transformer in accordance with an embodiment of this disclosure; and

FIG. 14 is a schematic perspective view of a transformer in accordance with an embodiment of this disclosure.

### DETAILED DESCRIPTION OF CERTAIN EMBODIMENTS

Various aspects of the novel systems, apparatuses, and methods are described more fully hereinafter with reference to the accompanying drawings. Aspects of this disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein, one skilled in the art should appreciate that the scope of the disclosure is intended to cover any aspect of the novel systems, apparatuses, and methods disclosed herein, whether implemented independently of or combined with any other aspect. For example, an apparatus may be implemented or a method may be practiced using any number of the aspects set forth herein. In addition, the scope is intended to encompass such an apparatus or method which is practiced using other structure, functionality, or structure and functionality in addition to or other than the various aspects set forth herein. It should be understood that any aspect disclosed herein may be embodied by one or more elements of a claim.

Although particular aspects are described herein, many variations and permutations of these aspects fall within the scope of the disclosure. Although some benefits and advantages of the preferred aspects are mentioned, the scope of the disclosure is not intended to be limited to particular benefits, uses, or objectives. Rather, aspects of the disclosure are intended to be broadly applicable to a variety of electronic systems including, for example, automotive systems and/or different wired and wireless technologies, system configurations, networks, including optical networks, hard disks, and transmission protocols. The detailed description and drawings are merely illustrative of the disclosure rather than limiting, the scope of the disclosure being defined by the appended claims and equivalents thereof.

This disclosure provides a compensation structure to compensate for core saturation non-uniformity of a magnetic core. This structure may include a coil in which the turns density varies across the coil. Turns density may be defined as the number of turns per unit length. By increasing the width of the conductors forming the coil, the turns density may be decreased. Turns density may be varied by having conductors of different thicknesses for each turn of the coil. It is thus possible to provide a magnetic component on or as part of an integrated circuit where the magnetic core saturates more uniformly. This can in turn give rise to greater linearity and improved power transfer within an operating region where substantially none of the core has reached magnetic saturation. This can be achieved without incurring an increased footprint for the magnetic component on a substrate, such as a semiconductor, on which the magnetic component is carried.

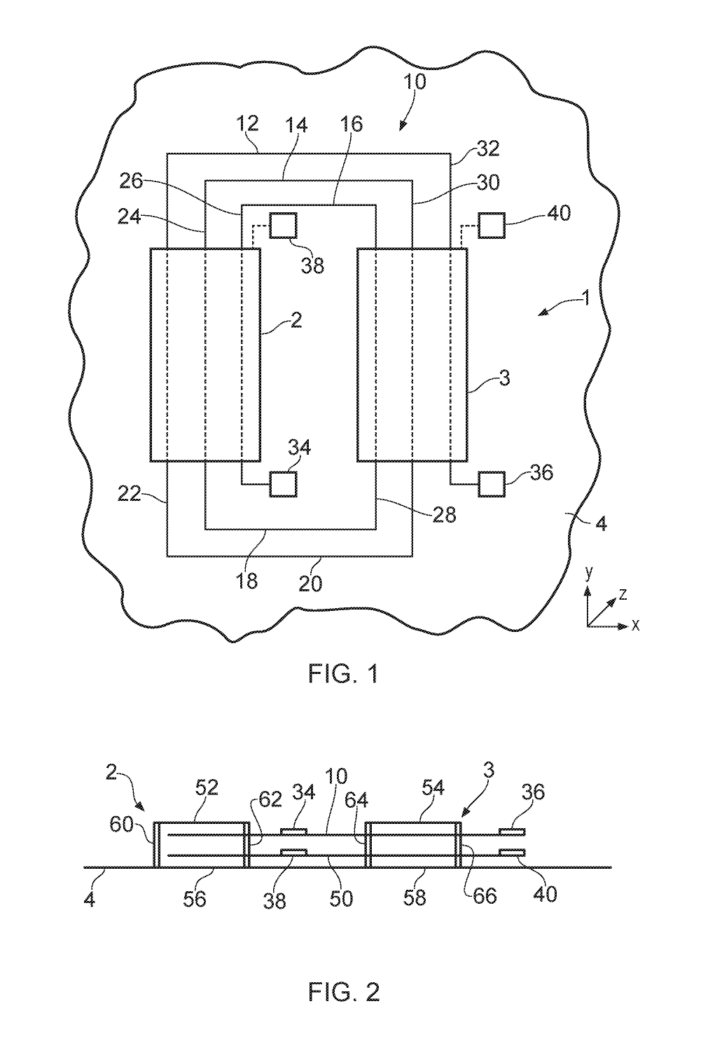

FIG. 1 schematically illustrates an example of a transformer 1. The transformer 1 has a two-part magnetic core. A first magnetic core is generally indicated by reference number 2 and a second magnetic core is generally indicated by reference number 3. The magnetic cores are formed as rectangular tubes in which the transformer coils are positioned, as will be explained in more detail below. The first and second magnetic cores 2, 3 are formed above a portion of a substrate 4. Advantageously the substrate 4 can be a semiconductor substrate (e.g., a silicon substrate) such that other components, such as drive circuitry and receiver circuitry associated with primary and secondary windings of the transformer 1, may be formed on the substrate 4 or on physically separate substrates within the same integrated circuit package. However, in some applications non-semiconductor substrate materials may be used for their electrical properties, such as higher impedance. Such non-semiconductor substrates can be implemented in accordance with any suitable principles and advantages discussed herein.

The transformer 1 includes two coils or windings. In FIG. 1, a primary winding 10 is shown. The primary winding 10 is formed from conductive tracks which are formed over the substrate 4. The primary winding 10 is formed from linear track sections 12, 14, 16, 18, 20, 22, 24, 26, 28, 30 and 32. Liner track sections 12, 14, 16, 18 and 20 are substantially parallel to each other and are formed in the X-direction. Linear track sections 22, 24, 26, 28, 30 and 32 are substantially parallel to each other and are formed in the Y-direction. The X-direction track sections are substantially perpendicular to the Y-direction track sections. The linear track sections are connected at their ends as shown in FIG. 1 in order to form the primary winding 10. The illustrated linear track sections are formed from a first metallic layer. At either end of the primary coil 10, connection pads 34, 36 are formed to enable connection of the transformer 1 to other components. A secondary winding (most of which is not shown in FIG. 1) may be formed from further linear track sections in a second metallic layer below the first metallic layer. These sections are not shown in FIG. 1 as they are formed below the track sections of the primary winding 10. However, the ends of the secondary coil have connection pads 38, 40, which may be seen in FIG. 1.

The primary and secondary windings are formed as planar spirals. The spiral of the primary winding 10 is in the same plane as the plane formed by the X and Y axes. The primary and secondary windings are insulated from the first and second magnetic cores 2, 3, and are insulated from one another. Thus there is no galvanic path between the primary winding 10 and secondary winding, and the primary mechanism coupling the coils together is a magnetic one. Minor parasitic capacitances may also form signal flow paths between the primary and secondary windings, but these are considerably less significant. The Z-direction in FIG. 1 is parallel to the coil axes.

FIG. 2 is an end view of the transformer 1. In this Figure, the secondary winding 50 is shown. This figure shows more clearly the first and second metallic layers of the primary and secondary windings 10, 50. Also shown are the connection pads 34, 36, 38 and 40. The first and second metallic layers are formed substantially parallel to the substrate 4. FIG. 2 also shows further details of the first and second magnetic cores 2, 3. Each core is formed from an upper magnetic layer 52, 54 and a lower magnetic layer 56, 58. These layers are illustrated as being rectangular in shape, and are substantially parallel to the substrate 4 and the first and second metallic layers. Each core 2, 3 extends beyond the edge of the outer and inner linear track of the primary and secondary windings 10, 50. The longer edges of the upper and lower magnetic layers are connected by vias 60, 62, 64 and 66 which are formed from magnetic material. As such, each core 2, 3 forms a rectangular tube through which the primary and secondary windings 10, 50 are formed.

In the above example, the magnetic vias 60, 62, 64, 66 also connect the upper 52, 54 and lower 56, 58 magnetic layers. In an alternative example, the vias may not completely bridge the space between the layers. Instead, a gap may be formed between the vias and, for example, the lower layer. This gap may be formed by providing a layer of insulating material between the ends of the vias and the lower layer using a material such as oxide, nitride or polyimide. The gap may be in the range of 10 nm to 500 nm. A benefit of such an arrangement is that an area of relatively high reluctance is formed in the core. This reduces permeability and helps reduce and/or prevent premature saturation.

In the above example, the planar nature of the coils give them the appearance of a racetrack, when viewed from above. Accordingly, transformer 1 may be referred to as a racetrack transformer.

For the purposes of illustration, structures around the magnetic cores 2, 3 such as layers of insulating material, for example polyimide, have been omitted. Thus the structures shown in FIGS. 1 and 2 are the substrate 4, the first and second magnetic cores 2, 3, and conductive tracks that form the primary and secondary windings 10, 50.

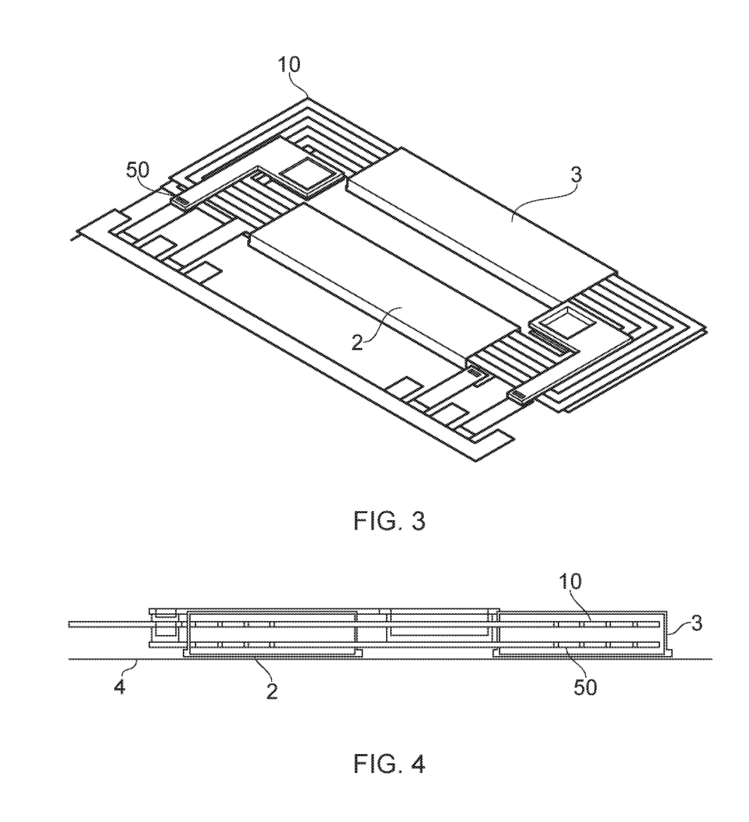

FIGS. 3 and 4 respectively show a perspective view and end view of a transformer of the type shown in FIGS. 1 and 2, as can be formed on an integrated circuit. It can be seen that the primary winding 10 and the secondary winding 50 spiral their way between the magnetic cores 2, 3. In the transformer shown in FIGS. 3 and 4 the width of each conductor forming a winding is uniform, as is the space between adjacent windings or conductors in either of the metallic layers of conductors. Generally speaking, the space between adjacent conductors in a layer can be substantially reduced, consistent with reducing the Ohmic resistance of the coil, while giving sufficient spacing to avoid shorting between coil turns as a result of manufacturing defects. The illustrated uniform windings can increase and/or maximize the number of turns for a given occupied area.

When forming a device, such as a transformer, the saturation current, being the maximum current which can be passed through the primary winding of the transformer before magnetic core saturation occurs, is a property of the transformer and its ferromagnetic core and is linked to the total power rating of the transformer. Therefore maximizing the saturation current and the power transfer of a given size transformer can be highly desirable.

A magnetic material can take a certain magnetic flux before it becomes magnetically saturated and its relative permeability dramatically drops (if the material is fully saturated then its permeability drops to 1). The relative permeability in combination with turns density of the coil and the saturation flux density determine device saturation current. However, the magnetic field drops towards the edges of the sections of the windings 10, 50 passing through the cores 2, 3. A further issue is the existence of a demagnetizing field. The demagnetizing field creates a magnetic field that is internal to the body of the core, and which acts in an opposite direction to the applied field from the coil. The demagnetizing field is strongest towards the long edges of the cores 2, 3. The spatial variation of demagnetizing field can be described in terms of spatial variation of the relative permeability. Because the demagnetizing field gets stronger towards the long edges of the core, the relative permeability drops towards the long edges and it takes higher current to magnetically saturate the long edges of the core than the center of the core.

In general terms, as windings 10, 50 get narrower, the demagnetizing field gets stronger. Also, the magnetic fields, both applied and demagnetizing, exist in three dimensions. Thus, although the magnetic cores are essentially planar they can experience some fields at their ends which are out of the plane of the planar core. This gives rise to different internal field strengths as a function of position within the magnetic core.

As a result of these factors, a ferromagnetic transformer core may suffer from early saturation of the central core area due to the uneven distribution of the magnetic flux density within the core. This onset of saturation, which grows in spatial extent as the bias current is increased, can introduce early non-ideal behavior of the transformer and can therefore limit the available saturation current.

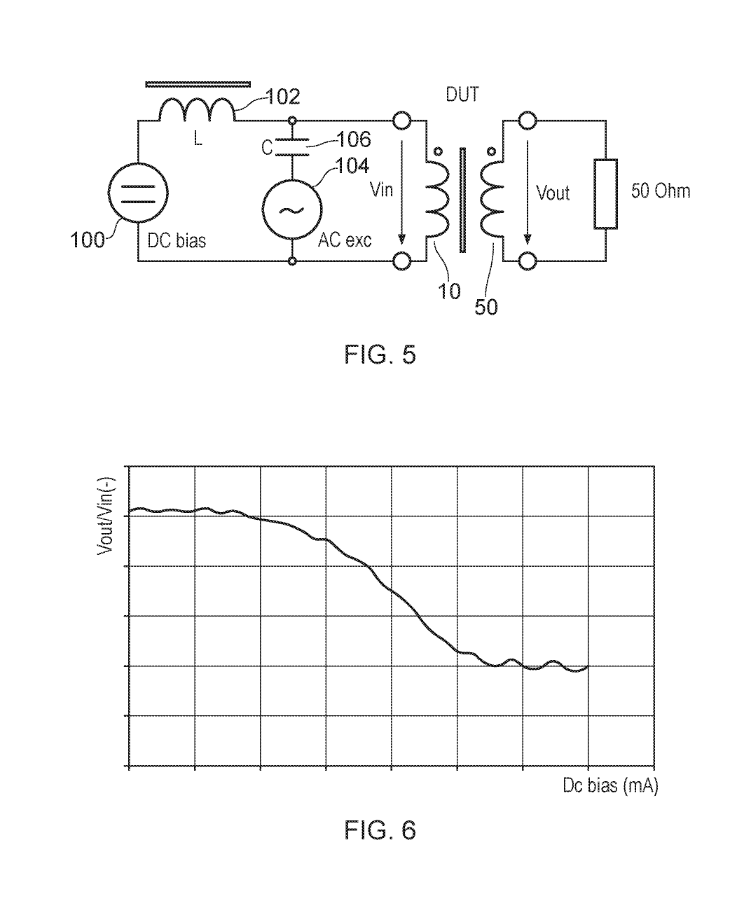

FIG. 5 shows an apparatus that can be used to measure the performance of the transformer. As shown, a direct current (DC) current bias 100, which could be a current source, is used to impose a DC current through the primary winding 10 of a transformer. An inductor 102 is typically included in series with the DC bias source 100 in order to present a high impedance to alternating current (AC) signals. An AC signal generator 104 in series with a DC blocking capacitor 106 is used to superimpose an AC signal onto the DC bias. The voltage appearing across the output of the secondary winding 50 is then measured, and then compared with the voltage provided by the AC excitation source 104. This allows the instantaneous AC power transfer of the transformer to be measured as a function of the DC bias current.

A graph illustrating measurement of this relationship is shown in FIG. 6 for a transformer with uniform windings. It can be seen that, at relatively low bias currents the ratio of a Vout to Vin is relatively high, and can be regarded as operating the transformer in a region where its core is not saturated. Therefore the effective permeability to a small change in primary current is representative of a high value of the relative permeability μr. Conversely, when the DC bias current becomes relatively large and the core is fully saturated, the output reduces to a smaller value, which is more akin to that of an air core transformer as the ferromagnetic core can no longer provide enhancement of the flux density as a result of a small change in the current.

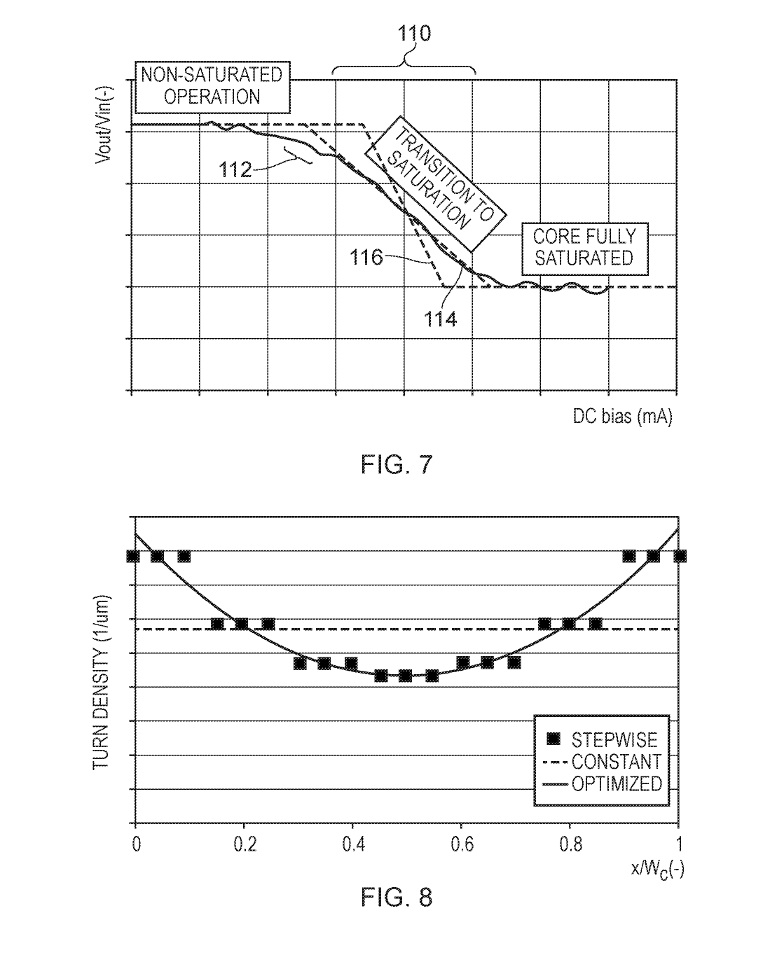

FIG. 7 re-plots the data of FIG. 6 to label the saturated and non-saturated regions, and also to apply straight line approximations to sections of the graph. Between the non-saturated region and the fully saturated region is a transition region, generally designated 110 where the permeability transitions from the non-saturated to the fully saturated values. Mathematical modelling indicates that the flux density B within the ferromagnetic core is non-uniform and is weaker at the edges or ends of the core, and more intense towards the center of the core. As a result, as the DC bias current increases the central portion of the core starts to saturate, indicated in FIG. 7 by the point at which the ratio starts to degrade around the area of the graph generally designated 112. The area of saturation then continues to grow from the middle to the ends until the core becomes fully saturated.

Preferably, the core transition to saturated state would start with higher bias current and it would transition more abruptly from non-saturated operation to saturated operation. This would enable a given size of magnetic core to handle more power and current before saturation occurs, although its performance would then degrade much more rapidly.

The inventor realized that steps could be taken to reduce the tendency of the central section of the magnetic core to saturate earlier than the edge sections of the magnetic core. This can be achieved by a structural feature of the magnetic component, and in an embodiment this is achieved by varying the turns density of the coil as a function of distance radially across the plane of the windings (e.g., the X-direction in FIG. 1). In FIG. 7, the dashed line 114 is for a coil with constant turns density. Dashed line 116 is for the expected result with a coil with varied and/or optimized turns density.

FIG. 8 is a graph schematically illustrating variation of turns density as a function of distance in the X-direction across the core 2 having a width of one arbitrary unit Wc. It can be seen that the turns density can be increased towards the edges of the core, as represented by values of x=0 and x=1, and decreased towards the center of the core, in order to reduce the tendency for early saturation of the central section.

The dimensions of a coil within a magnetic core within an integrated circuit are quite compact, and it is therefore unlikely that the turns would be modified in a smoothly varying manner represented by the optimized curve in FIG. 8, but a step wise approximation is possible as shown in FIG. 8.

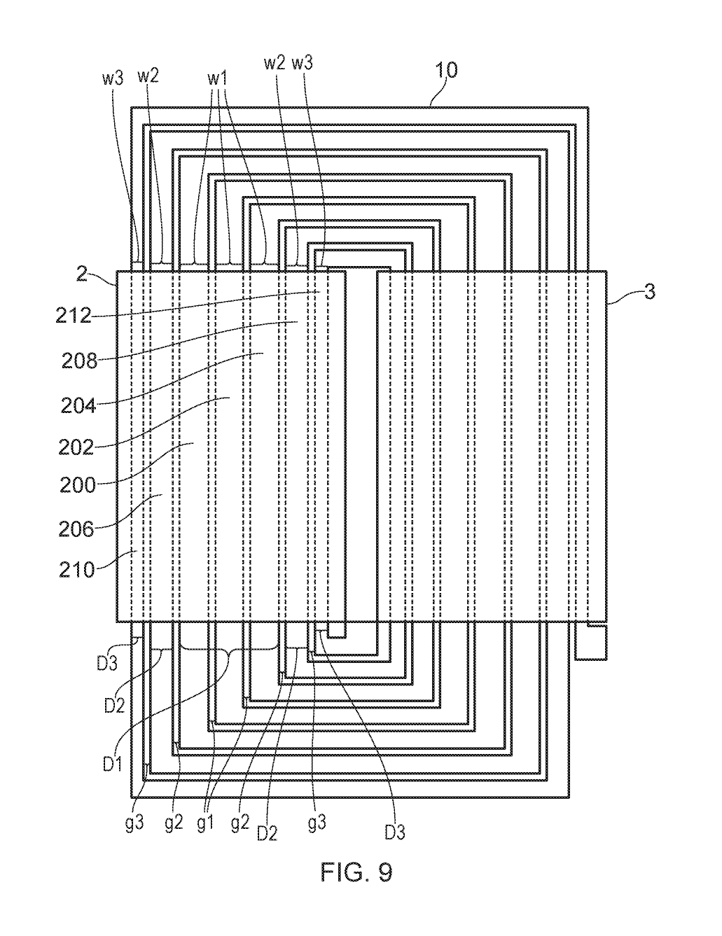

As a result of applying a step wise approximation to the turns density, a winding density as shown in FIG. 9 may be achieved where the coil may comprise spaced apart conductors, of which the primary winding 10 is shown, but a corresponding pattern can also be formed on the secondary winding 50 beneath the primary winding 10. The conductor strips are arranged to give a coil having a relatively low winding density, designated density D1, towards a central portion of the coil, and an intermediate winding density, designated density D2, on either side of the area at the center of the coil. Either edge of the coil has a higher winding density, designated density D3, compared to the central and intermediate densities. In the illustrated embodiment, differing densities are achieved by varying the conductor widths at different sections of the coil. The first section of the coil comprises relatively wide strips of conducting material designated 200, 202 and 204 having a width w1 and an inter-conductor gap distance g1. The intermediate areas of coil density, density D2, are comprised of conductors 206 and 208 having a conductor width w2 and an inter conductor gap spacing g2. The end portions having the highest winding density, density D3, are comprised of conductors 210 and 212, having a width to w3 and an inter conductor spacing g3. As such, the coil is a compensation structure that compensates for core saturation non-uniformity of the magnetic core.

It would be possible to vary the gap between the conductors, and keep the conductor width the same such that w1=w2=w3 and g3>g2>g1. However this arrangement, while giving generally desirable magnetic properties, can give rise to an increase in resistance of the coil compared to that which could be obtained by keeping the gap between the adjacent conductors the same, such that g1=g2=g3, and then varying the relative width of the conductive elements w1, w2 and w3 such that w1>w2>w3. Varying the widths of the conductors forming the coils, rather than varying the dielectric gaps, increases and/or maximizes the amount of conductor (for a given thickness of conductor) involved in carrying the current through the coil, and thereby reduces resistance.

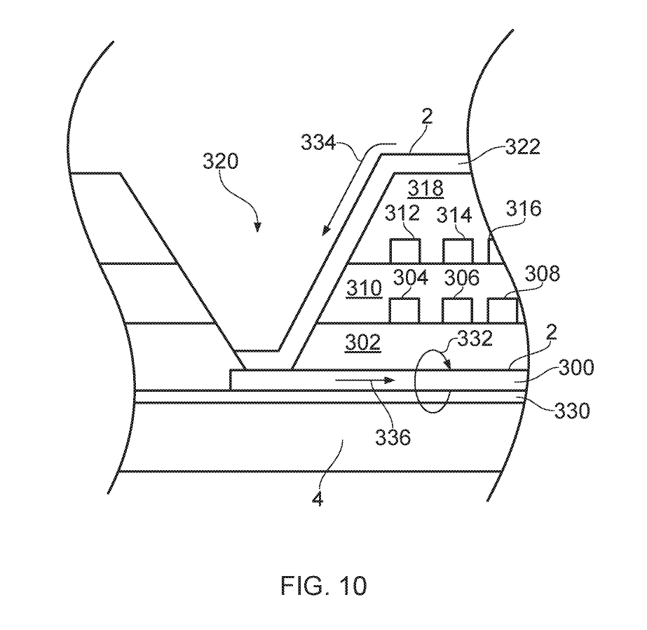

FIG. 10 is a schematic cross-section through an integrated circuit including a transformer having a magnetic core, generally indicated by reference numeral 2. As shown in FIG. 10, the integrated circuit comprises a substrate 4 which has a lowermost magnetic layer 300 deposited thereon. After deposition, the magnetic layer 300 is masked and etched so as to form a lower side of the core 2. It will be understood that the structure of FIG. 10 can be combined with the turns density variation described with respect to FIG. 9. An insulating layer 302, for example of polyimide, is then deposited above the magnetic layer 300 to insulate the magnetic core from the transformer windings. The windings 304, 306, 308 of the secondary coil 50 are then deposited, for example by electroplating across the entirety of the substrate. The structure is then masked and then etched so as to form isolated metallic coil regions above the insulating layer 302. Additional insulating material may then be deposited to fill in the gaps between adjacent coils to encapsulate them within a dielectric. Such an insulating layer is designated as 310 in FIG. 10. The windings 312, 314, 316 of the primary coil 10 are then deposited, for example by electroplating across the entirety of the substrate. The structure is then masked and then etched so as to form isolated metallic coil regions above the insulating layer 310. Additional insulating material may then be deposited to fill in the gaps between adjacent coils to encapsulate them within a dielectric. Such an insulating layer is designated as 318 in FIG. 10.

The insulating layer 318 may then be subject to planarizing in order to form a substantially flat upper surface of the integrated circuit. As each layer of insulator is fabricated, its surface may be masked, using a material such as polyimide, and can be etched in order to form a gap in each of the insulating layers 302, 310, 318. Once all of the layers have been fabricated, the gaps can form depression 320 which extends down to the lowermost magnetic layer 300. The upper surface of insulating layer 318 may then have a magnetic layer 322 deposited on it. The magnetic layer can also be deposited into the V-shaped depression 320 thereby forming a connection between the lowermost magnetic layer 300 and the uppermost magnetic layer 322. The layer 322 can then be masked and etched in order to form, amongst other things, the upper portion of the core 2.

The lowermost magnetic layer 300 may be formed over an insulating layer 330, for example of silicon dioxide or any other suitable dielectric material, which may itself overlie various semiconductor devices (not shown) formed by implantation of donor or acceptor impurities into the substrate 4. As known to the person skilled in the art, apertures may be formed in the insulating layers 302, 310, 318 in order to form device interconnections among the various circuit components.

Each layer of the magnetic core 300, 322 may comprise a plurality of sub-layers. For example, each layer may include four sub-layers. The magnetic core 2 may also comprise a plurality of first insulating layers arranged in an alternating sequence with sub-layers of magnetically functional material. In this example, four layers of insulating material sit above the four sub-layers of magnetic material in an alternating stack. It should be noted that fewer, or indeed more, layers of magnetically functional material and insulating material may be used to form the core 2. Magnetic core 3 is formed in the similar manner. These sub-layers, for example, can help prevent, or reduce, the build-up of eddy currents.

The sub-layers of the insulating material may be aluminum nitride (although other insulating materials such as aluminum oxide may be used for some or all of the layers of insulating material), and may have thicknesses in the range of 3 to 20 nanometers. The magnetically active layers can be formed of nickel iron, nickel cobalt or composites of cobalt or iron with one or more of the elements zirconium, niobium, tantalum and boron. The magnetically active layers may typically have a thickness in the range of 50 to 300 nanometers. Magnetic flux flows around the core 2 in the direction shown by arrows 334 and 336. As such, eddy currents that move in the direction indicated by arrow 332 are significantly reduced by the above-described sub-layers. This is because the sub-layers are formed substantially perpendicular to the direction of flow of at least a part of the eddy current flow-path.

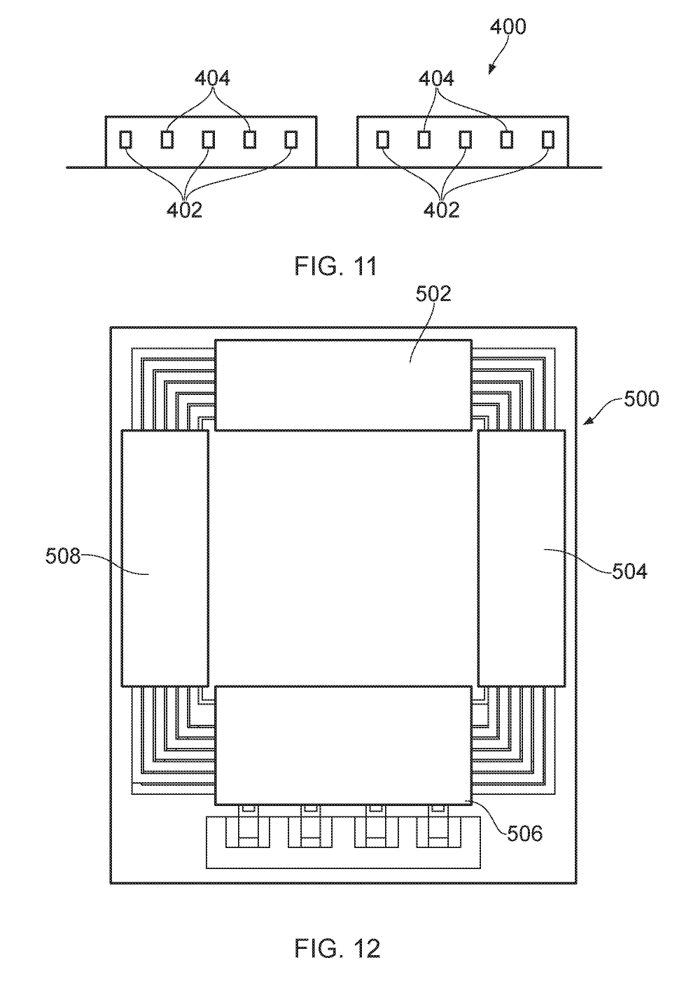

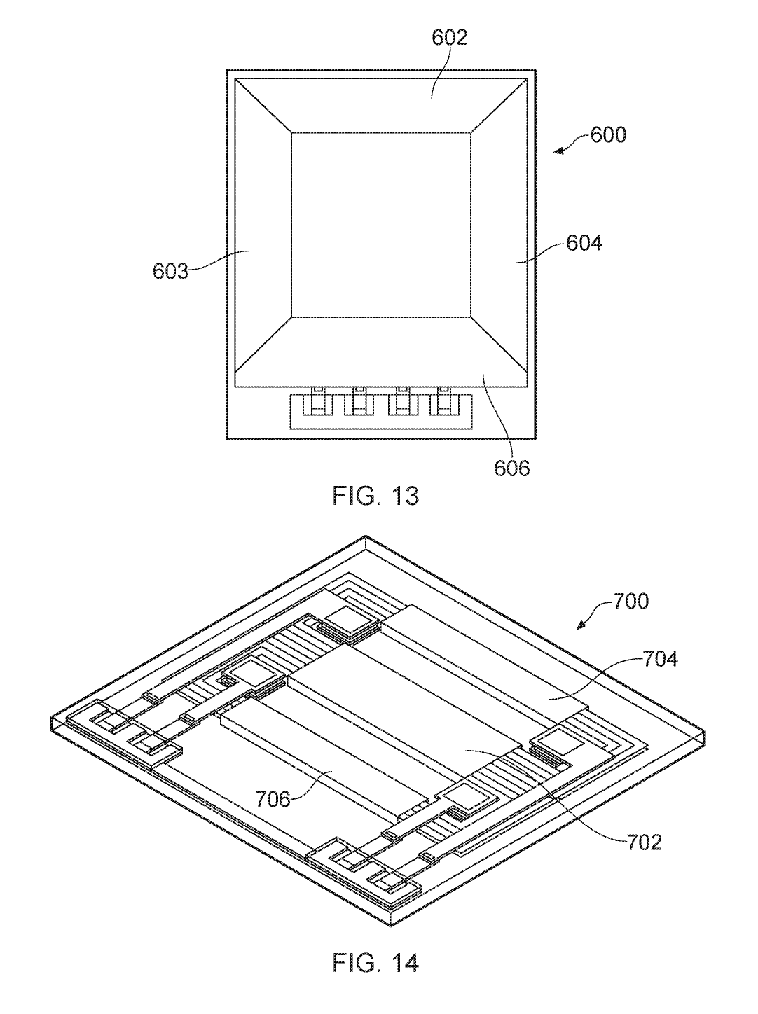

Although a rectangular two-winding dual-core transformer has been described, other planar transformer designs are possible. For example, additional metallic layers may be provided, or additional coils may be provided in a given layer, in order to increase the number of coils. Also a single tapped winding may be used to form an autotransformer, or a single winding may be used to form an inductor. Furthermore, the windings could be formed in a single layer in a co-wound arrangement. Such an example is shown in FIG. 11. In FIG. 11, a transformer 400 is shown including a primary coil 402 and a secondary coil 404. Coils 402, 404 are co-wound in a single layer of metal. In a further alternative, the windings could be square when viewed from above. This is shown in FIGS. 12 and 13. In FIG. 12, a transformer 500 is shown. The transformer 500 includes four magnetic cores 502, 504, 506 and 508. In FIG. 13, a square transformer 600 is shown. In this example, the cores 602, 604, 606 and 608 extend into the corners, and are trapezoidal in shape. As a further alternative, as shown in FIG. 14, a so-called dual racetrack transformer 700 may be formed. The overlapping portions may be wrapped in a first magnetic core 702, whereas the non-overlapping portions may be wrapped in second and third magnetic cores 704, 706. Any and all of these examples may be combined with the varying turn density shown in FIG. 9.

In the afore-mentioned embodiments, the one example of the compensation structure has been described in which the turns density of a coil is varied by adjusting the thickness of the conductive elements. As an alternative, the compensation structure may include the core itself. For example, the length of the core (in the Y-direction in FIG. 1) may vary across the core (in the X-direction in FIG. 1). As such, the length of the core at the edges of the core in the area adjacent the inner and outer conductors 210, 212 is shorter than the length of the core in the area adjacent the inner conductors 200, 202, 204. Such an arrangement would compensate for core saturation non-uniformity in a similar way to varying the turns density of the coil.

The disclosed technology can be implemented in any application or in any device with a need for a magnetic core with reduced core saturation non-uniformity. Aspects of this disclosure can be implemented in various electronic devices. Examples of the electronic devices can include, but are not limited to, consumer electronic products, parts of the electronic products, electronic test equipment, cellular communications infrastructure, etc. Examples of the electronic devices can include, but are not limited to, precision instruments, medical devices, wireless devices, a mobile phone such as a smart phone, a telephone, a television, a computer monitor, a computer, a modem, a hand-held computer, a laptop computer, a tablet computer, a wearable computing device such as a smart watch, a personal digital assistant (PDA), a vehicular electronics system, a microwave, a refrigerator, a vehicular electronics system such as automotive electronics system, a stereo system, a DVD player, a CD player, a digital music player such as an MP3 player, a radio, a camcorder, a camera, a digital camera, a portable memory chip, a washer, a dryer, a washer/dryer, a wrist watch, a clock, etc. Further, the electronic devices can include unfinished products.

Unless the context clearly requires otherwise, throughout the description and the claims, the words “comprise,” “comprising,” “include,” “including,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description of Certain Embodiments using the singular or plural number may also include the plural or singular number respectively. Where the context permits, the word “or” in reference to a list of two or more items is intended to cover all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The phrase “adjacent” may be taken to mean that a first material may be placed in close proximity to the second material, which may occur if a relatively thin layer of a third material is placed between the first and the second materials, such as an insulator. In this context, the first material is “adjacent” the second material.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while the disclosed embodiments are presented in a given arrangement, alternative embodiments may perform similar functionalities with different components and/or circuit topologies, and some elements may be deleted, moved, added, subdivided, combined, and/or modified. Each of these elements may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

Although the claims presented here are in single dependency format for filing at the USPTO, it is to be understood that any claim may depend on any preceding claim of the same type except when that is clearly not technically feasible.

1. An inductive component for use in an integrated circuit, the inductive component comprising:
at least one conductor arranged in a spiral path to form a first coil;
a first layer of magnetic material arranged on or adjacent at least a portion of a first side of the at least one conductor, the first layer of magnetic material being included in at least one magnetic core; and
a compensation structure configured to compensate for core saturation non-uniformity of the at least one magnetic core.

2. An inductive component as claimed in claim 1, where the compensation structure comprises the first coil, and a turns density of the first coil varies as a function of position in a radial direction across the first coil to thereby compensate for core saturation non-uniformity of the at least one magnetic core.

3. An inductive component as claimed in claim 2, in which the spiral path includes a center conductor, an inner edge conductor, and an outer edge conductor and the turns density is greater towards the inner and outer edge conductors than the center conductor.

4. An inductive component as claimed in claim 2, in which the at least one magnetic core comprises a magnetic core that extends across a radial width of the first coil and the turns density is reduced with increasing distance from an edge of the magnetic core.

5. An inductive component as claimed in claim 2, in which the turns density is dependent on a width of a conductor of the at least one conductor forming a turn of the first coil.

6. An inductive component as claimed in claim 2, in which the turns density varies in a region of the first coil corresponding to the first layer of magnetic material.

7. An inductive component as claimed in claim 1, wherein the at least one magnetic core further comprises a second layer of magnetic material arranged adjacent a second side of the at least one conductor, and in a position opposite to the first layer of magnetic material.

8. An inductive component as claimed in claim 7, wherein the at least one magnetic core is arranged to form a passage therethrough which the at least one conductor of the first coil passes through.

9. An inductive component as claimed in claim 1, in which the first coil is substantially planar and a plane of the first layer of magnetic material is substantially perpendicular to an axis of the first coil.

10. (canceled)

11. An inductive component as claimed in claim 1, in which the inductive component is a transformer.

12. An inductive component as claimed in claim 11, further comprising at least one second conductor arranged in a spiral path to form a second coil, the second coil being magnetically coupled with the at least one magnetic core.

13. An inductive component as claimed in claim 12, in which the first coil and the second coil are co-axial.

14. An inductive component as claimed in claim 12, in which the first coil and the second coil are formed in the same layer of the inductive component.

15. An inductive component as claimed in claim 12, in which the second coil has a spatially varying turns density.

16. An inductive component as claimed in claim 1, wherein the one magnetic core is wrapped around at least a portion of the first coil.

17. (canceled)

18. (canceled)

19. (canceled)

20. An integrated circuit comprising an inductive component that includes a planar spiral coil, wherein an instantaneous turns density of the planar spiral coil varies across a width of the planar spiral coil from an edge conductor of the planar spiral coil to a center conductor of the planar spiral coil.

21. An inductive component comprising:
at least one conductor arranged in a spiral path to form a first spiral coil; and
at least one magnetic core wrapped around at least a portion of the first spiral coil;
wherein the first spiral coil extends through a passage in the at least one magnetic core; and
wherein the first spiral coil has a turns density that varies as a function of position in a radial direction across the first spiral coil to thereby compensate for core saturation non-uniformity of the at least one magnetic core.

22. An inductive component as claimed in claim 21, further comprising a second spiral coil, wherein the inductive component is a transformer that comprises the first spiral coil and the second spiral coil.

23. An inductive component as claimed in claim 21, wherein the turns density is dependent on a width of a conductor of the at least one conductor forming a turn of the first spiral coil.

24. An inductive component as claimed in claim 21, wherein the inductive component is an inductor.
